(19) United States
(12) Patent Application Publication
(10) Pub. No.: US 2015/0114553 A1
(43) Pub. Date: Apr. 30, 2015

(54) METHOD OF MANUFACTURING GLASS CORE

(71) Applicant: SAMSUNG ELECTRO-MECHANICS CO., LTD., Suwon (KR)

(72) Inventors: Tae Hong MIN, Suwon (KR); Suk Hyeon Cho, Suwon (KR); Sang Hoon Kim, Gunpo (KR); Hye Jin Kim, Yongin (KR); Young Gwan Ko, Suwon (KR); Jung Han Lee, Seoul (KR)

(73) Assignee: SAMSUNG ELECTRO-MECHANICS CO., LTD., Suwon (KR)

(21) Appl. No.: 14/460,434

(22) Filed: Aug. 15, 2014

(30) Foreign Application Priority Data
Oct. 30, 2013 (KR) 10-2013-0130194

(51) Int. Cl. H05K 3/00; B32B 38/10; B32B 37/18; B32B 38/00

(52) U.S. Cl. CPC H05K 3/007; B32B 38/0008; B32B 38/0004; B32B 38/0036; B32B 38/10; B32B 37/18
USPC 156/247

(57) ABSTRACT

Disclosed herein is a method of manufacturing a glass core capable of continuously manufacturing the glass core by an automated process. The method includes: providing a glass sheet; laminating an insulating sheet on the glass sheet; laminating a copper clad sheet on the insulating sheet to manufacture the glass core; laminating a buffering sheet on the copper clad sheet; pressing and temporarily hardening the buffering sheet; delaminating the temporarily hardened buffering sheet; thermally hardening the glass core by a heater after the delaminating of the temporarily hardened buffering sheet; and cutting the glass core at a predetermined size after the thermal hardening of the glass core.

### CROSS REFERENCE(S) TO RELATED APPLICATIONS

This application claims the foreign priority benefit of Korean Patent Application Serial No. 10-2013-0130194, entitled “Method of Manufacturing Glass Core” filed on Oct. 30, 2013, which is hereby incorporated by reference in its entirety into this application.

### BACKGROUND OF THE INVENTION

1. Technical Field

The present invention relates to a method of manufacturing a glass core, and more particularly, to a method of manufacturing a glass core capable of continuously manufacturing the glass core by an automated process.

2. Description of the Related Art

An example of a multilayer printed board includes a large multilayer printed board for a motherboard and a small multilayer printed board (called a semiconductor package board) for a system in package (SIP).

Recently, in accordance with development of a high density mounting technology of a semiconductor, a semiconductor package board including fine patterns has been prominent.

According to the related art, in the case of mounting a semiconductor device on the semiconductor package board in a flip chip scheme, the semiconductor package board needs to have sufficient mechanical strength in order to secure mounting reliability.

For this reason, an inner circuit plate having mechanical strength and any thickness has been used as the semiconductor package board.

However, due to multi-layering depending on high integration and high density mounting, a thickness of the semiconductor package board obtained in the case in which the inner circuit plate is laminated is increased.

Meanwhile, the multilayer printed board is mainly manufactured in a build-up scheme in which insulating resin films and conductor circuit layers are alternately laminated on the inner circuit plate.

In a method of manufacturing the multilayer printed board in the build-up scheme, an insulating resin film to which a carrier is attached is used in order to form the insulating resin film. In order to secure mechanical strength against thinness of the multilayer printed board, various studies on the insulating resin film to which the carrier is attached have been conducted.

For example, a method of obtaining a multilayer printed board having improved mechanical strength and mounting reliability using a carrier attached prepreg in which a prepreg is used as the insulating resin film has been devised.

In addition, a copper clad laminate of the multilayer printed board is configured so that a predetermined thickness is maintained in order to decrease warpage of the multilayer printed board and a semiconductor device may be embedded therein. The copper clad laminate is manufactured by laminating insulating resin films on both surfaces of a glass fabric using a roll laminate apparatus to manufacture a prepreg and laminating copper clad sheets on both sides of the prepreg.

However, in the copper clad laminate according to the related art, a reinforcing material such as a glass cloth or a glass fabric has been included in a resin to decrease warpage. However, the warpage of the board is not sufficiently decreased only by the reinforcing material. Particularly, since a process of manufacturing the copper clad laminate is not stable, such that a defective rate has not been decreased.

### SUMMARY OF THE INVENTION

An object of the present invention is to provide a method of manufacturing a glass core capable of significantly decreasing warpage of a board and significantly decreasing a defective rate by an automated manufacturing process.

According to an exemplary embodiment of the present invention, there is provided a method of manufacturing a glass core, including: providing a glass sheet; laminating an insulating sheet on the glass sheet; laminating a copper clad sheet on the insulating sheet to manufacture the glass core; laminating a buffering sheet on the copper clad sheet; pressing and temporarily hardening the buffering sheet; delaminating the temporarily hardened buffering sheet; thermally hardening the glass core by a heater after the delaminating of the temporarily hardened buffering sheet; and cutting the glass core at a predetermined size after the thermal hardening of the glass core.

The method may further include, after the providing of the glass sheet, activating a surface of the glass sheet using plasma in order to increase close adhesion between the glass sheet and the insulating sheet.

The glass sheet may have a thickness of 30 to 150 μm, and the insulating sheet may be a polypropylene glycol (PPG) sheet or an Ajinomoto build-up film (ABF) sheet.

The delaminating of the temporarily hardened buffering sheet may be performed by a buffering sheet winder, wherein the buffering sheet winder includes a rotating roll and an adhesive tape part connected to the rotating roll.

The thermal hardening of the glass core may be performed by any one of hot wind and an infrared (IR) lamp.

In the cutting of the glass core, the glass core may be cut at predetermined intervals by laser or dicing.

### BRIEF DESCRIPTION OF THE DRAWINGS

FIG. 1 is an illustrative diagram showing a process of manufacturing a glass core according to an exemplary embodiment of the present invention; and

FIG. 2 is an illustrative diagram showing a delaminating process of a buffering sheet in the process of manufacturing a glass core according to the exemplary embodiment of the present invention.

### DESCRIPTION OF THE PREFERRED EMBODIMENTS

Hereinafter, exemplary embodiments of the present invention will be described in detail with reference to the accompanying drawings.

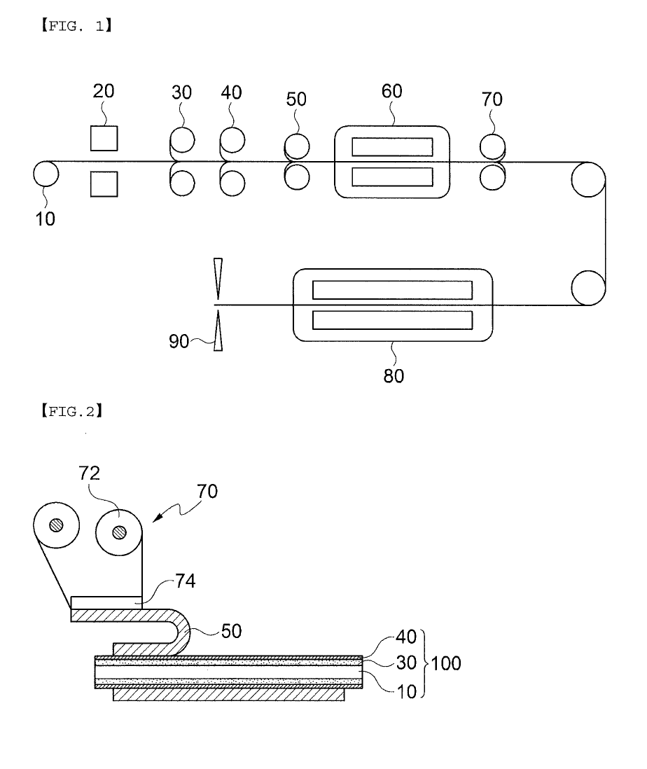

FIG. 1 is an illustrative diagram showing a process of manufacturing a glass core according to an exemplary embodiment of the present invention; and FIG. 2 is an illustrative diagram showing a delaminating process of a buffering sheet in the process of manufacturing a glass core according to the exemplary embodiment of the present invention.

As shown, in a method of manufacturing a glass core according to the exemplary embodiment of the present invention, first, a glass sheet 10 wound in a roll form is continuously unwound by a transfer device (not shown). An insulating sheet 30, a copper clad sheet 40, and a buffering sheet 50 are sequentially laminated on the unwound glass sheet 10 and then temporarily hardened by a press 60. When the temporal hardening is completed, the buffering sheet 50 is delaminated, and the glass core is thermally hardened by a heater 80. After the thermal hardening is completed, the glass core is cut at a predetermined size by a cutter 90.

The glass sheet 10 is maintained at a thickness of 30 to 150 μm. In the case in which the glass sheet 10 has a thickness thinner than 30 μm, the glass sheet 10 may be easily damaged at the time of being pressed by the press 60. To the contrary, the glass sheet 10 may have a thickness of about 200 μm in excess of 150 μm. However, recently, since the glass core is not substantially manufactured at a thickness of 150 μm or more, a thickness of the glass sheet 10 is maintained at 150 μm or less.

Therefore, it is preferable that the glass sheet 10 according to the exemplary embodiment of the present invention has a thickness of 30 to 150 μm.

When the glass sheet 10 is unwound by a transfer roll, surface activation is performed by plasma air 20 in order to increase close adhesion between the glass sheet 10 and the insulating sheet 30. That is, when plasma treatment is performed on a surface of the glass sheet 10, hydrogen bonds between the glass sheet 10 and the insulating sheet 30 are made well, such that close adhesion between the glass sheet 10 and the insulating sheet 30 may be increased.

When the plasma treatment is performed on the surface of the glass sheet 10, the insulating sheets 30 are disposed on upper and lower surfaces of the glass sheet 10, respectively. The insulating sheet 30 may have a width equal to or larger than that of the glass sheet 10.

The glass sheet 10 according to the exemplary embodiment of the present invention may be made of a polypropylene glycol (PPG) resin or an Ajinomoto build-up film (ABF) resin, which is an insulating material.

After the insulating sheets 30 are laminated on the glass sheet 10, the copper clad sheets 40 are laminated on the insulating sheet 30. The copper clad sheet 40 is unwound in accord with a movement speed of the glass sheet 10 in the state in which it is wound in a roll form.

After the copper clad sheets 40 are laminated on the insulating sheets 30, a pressing process is performed by the press so that the insulating sheets 30 and the copper clad sheets 40 on the upper and lower surfaces of the glass sheet 10 are integrated with each other.

Here, in order to perform the pressing process, a buffering material is required so that a crack is not generated in the glass sheet 10 by pressure of the press 60.

Therefore, the buffering sheet 50 is laminated on an upper surface of the copper clad sheet 40. The buffering sheet 50 may have a thickness of about 50 μm so as to have sufficient buffering force against pressure of the press.

After the buffering sheet 50 is laminated on the copper clad sheet 40, press processing is performed. The insulating sheets 30 and the copper clad sheets 40 laminated on the upper and lower surfaces of the glass sheet 10 are temporarily hardened by the press processing, such that the glass core 100 is formed.

When the glass core 100 is completed as described above, a process of delaminating the buffering sheets 50 attached to both sides of the glass core 100 is performed.

The buffering sheets 50 may be delaminated by a buffering sheet winder 70. The buffering sheet winder 70 includes a rotating roll 72 and an adhesive tape part 74.

The rotating roll 72 is connected to the adhesive tape part 74, and the adhesive tape part 74 ascends and descends depending on a rotation direction of the rotating roll 72.

That is, when the rotating roll 72 rotates in the state in which the adhesive tape part 74 is attached to the buffering sheet 50, the adhesive tape part 74 ascends and descends depending on the rotation direction of the rotating roll 72, for example, ascends in the case in which the rotating roll 72 rotates in a clockwise direction and descends in the case in which the rotating roll 72 rotates in a counterclockwise direction.

Therefore, when the buffering sheet 50 moves to a position at which the buffering sheet winder 70 is installed in the case in which the buffering sheet 50 is closely adhered to the glass core 100, the rotating roll 72 rotates in the counterclockwise direction, such that the adhesive tape part 74 is closely adhered to the buffering sheet 50 while descending. The adhesive tape part 74 closely adhered to the buffering sheet 50 ascends together with the buffering sheet 50 by rotation of the rotating roll in the clockwise direction to delaminate the buffering sheet 50 from the glass core 100.

When the buffering sheet 50 is delaminated from the glass core 100 through the above-mentioned process, the glass core 100 is thermally hardened by the heater 80.

As the thermal hardening process by the heater 80, any one of a hardening process by hot wind and a hardening process by an infrared (IR) lamp may be used or a mixture thereof may be used depending on a design.

When the glass core 100 is in a completely hardened state by the thermal hardening process, the glass core 100 is cut at a predetermined size by the cutter 90.

Although the case in which the glass core 100 is subjected to the thermal hardening process and then cut by the cutter 90 has been shown and described in the accompanying drawings and the detailed description, after the glass core 100 is cut by the cutter 90, a plurality of glass cores 100 may be laminated and be then subjected to the thermal hardening process.

In addition, although the glass core 100 may be cut by the press, it is preferable that the glass core 100 is cut by laser or dicing since brittleness of the glass sheet 10 is very large.

As described above, in the method of manufacturing a glass core according to the exemplary embodiment of the present invention, since the insulating sheets 30 and the copper clad sheets 40 may be continuously laminated based on the glass sheet 10 by an automated process, the glass cores may be mass-produced. Particularly, warpage of all glass cores 100 may be minimized by the glass sheet 10, such that product characteristics may be improved.

With the method of manufacturing a glass core according to the exemplary embodiment of the present invention, warpage of a board may be significantly decreased and a defective rate may be significantly decreased by an automated manufacturing process, such that product characteristics and productivity may be improved.

Hereinabove, although the method of manufacturing a glass core according to the exemplary embodiment of the present invention has been described, the present invention is not limited thereto, but may be variously modified and altered by those skilled in the art.

What is claimed is:

1. A method of manufacturing a glass core, comprising:
providing a glass sheet;
laminating an insulating sheet on the glass sheet;
laminating a copper clad sheet on the insulating sheet to manufacture the glass core;
laminating a buffering sheet on the copper clad sheet;
pressing and temporarily hardening the buffering sheet;
delaminating the temporarily hardened buffering sheet;
thermally hardening the glass core by a heater after the delaminating of the temporarily hardened buffering sheet; and
cutting the glass core at a predetermined size after the thermal hardening of the glass core.

2. The method according to claim 1, further comprising, after the providing of the glass sheet, activating a surface of the glass sheet using plasma in order to increase close adhesion between the glass sheet and the insulating sheet.

3. The method according to claim 1, wherein the glass sheet has a thickness of 30 to 150 μm.

4. The method according to claim 1, wherein the insulating sheet is a polypropylene glycol (PPG) sheet or an Ajinomoto build-up film (ABF) sheet.

5. The method according to claim 1, wherein the delaminating of the temporarily hardened buffering sheet is performed by a buffering sheet winder.

6. The method according to claim 5, wherein the buffering sheet winder includes a rotating roll and an adhesive tape part connected to the rotating roll.

7. The method according to claim 1, wherein the thermal hardening of the glass core is performed by any one of hot wind and an infrared (IR) lamp.

8. The method according to claim 1, wherein in the cutting of the glass core, the glass core is cut at predetermined intervals by laser or dicing.
